(19) United States
(12) Patent Application Publication
(10) Pub. No.: US 2025/0279263 A1
(43) Pub. Date: Sep. 4, 2025

(54) ETCHING METHOD AND PLASMA PROCESSING APPARATUS

(71) Applicant: Tokyo Electron Limited, Tokyo (JP)

(72) Inventors: Shota YAMAZAKI, Miyagi (JP); Yusuke TAKINO, Miyagi (JP); Ryo MATSUBARA, Miyagi (JP); Sho KUMAKURA, Miyagi (JP)

(73) Assignee: Tokyo Electron Limited, Tokyo (JP)

(21) Appl. No.: 19/214,064

(22) Filed: May 21, 2025

Related U.S. Application Data
(63) Continuation of application No. PCT/JP2023/042868, filed on Nov. 30, 2023.

(30) Foreign Application Priority Data
Dec. 1, 2022 (JP) 2022-192621

(51) Int. Cl. H01J 37/32; H01L 21/3065; H01L 21/308

(52) U.S. Cl. CPC H01J 37/32449; H01L 21/3065; H01L 21/308; H01J 2237/334

(57) ABSTRACT

To provide a technique of preventing shape abnormalities due to etching of a silicon film. An etching method includes: (a) providing, on a substrate support disposed in a chamber, a substrate that includes a silicon film or a silicon-containing conductive film and a mask on the silicon film or the silicon-containing conductive film, and (b) supplying, into the chamber, a processing gas that contains a bromine containing gas, a phosphorus fluoride gas, and an oxygen containing gas, and generating a plasma from the processing gas to etch the silicon film or the silicon-containing conductive film.

### CROSS-REFERENCE TO RELATED APPLICATIONS

This application is a bypass continuation application of international application No. PCT/JP2023/042868 having an international filing date of Nov. 30, 2023 and designating the United States, the international application being based upon and claiming the benefit of priority from Japanese Patent Application No. 2022-192621, filed on Dec. 1, 2022, the entire contents of each are incorporated herein by reference.

### TECHNICAL FIELD

Exemplary embodiments of the present disclosure relate to an etching method and a plasma processing apparatus.

### BACKGROUND

Patent Document 1 discloses a technique of etching a silicon-containing film.

### CITATION LIST

### Patent Documents

Patent Document 1: US2016/0343580

### SUMMARY

The present disclosure provides a technique of preventing shape abnormalities due to etching of a silicon film.

The etching method in one exemplary embodiment of the present disclosure includes: (a) providing, on a substrate support disposed in a chamber, a substrate that includes a silicon film or a silicon-containing conductive film and a mask on the silicon film or the silicon-containing conductive film, and (b) supplying, into the chamber, a processing gas that contains a bromine containing gas, a phosphorus fluoride gas, and an oxygen containing gas, and generating a plasma from the processing gas to etch the silicon film or the silicon-containing conductive film.

According to one exemplary embodiment of the present disclosure, a technique of preventing shape abnormalities due to etching of the silicon film can be provided.

### BRIEF DESCRIPTION OF DRAWINGS

FIG. 1 is a diagram illustrating an example of a configuration of a plasma processing system.

FIG. 2 illustrates an example of a configuration of a capacitively coupled plasma processing apparatus.

FIG. 3 is a flowchart illustrating an example of an etching method.

FIG. 4 is a diagram illustrating an example of a cross-sectional structure of a substrate.

FIG. 5 is a diagram illustrating an example of a cross-sectional structure of the substrate during processing of step ST2.

FIG. 6 is a diagram illustrating an amount of F radicals generated when a plasma is generated using various gases.

FIG. 7 is a diagram illustrating results of etching a silicon film when a PF₃ gas and an NF₃ gas are used as part of a processing gas.

### DETAILED DESCRIPTION

An embodiment of the present disclosure will be described below.

In one exemplary embodiment, an etching method is provided, which includes: (a) providing, on a substrate support disposed in a chamber, a substrate that includes a silicon film or a silicon-containing conductive film and a mask on the silicon film or the silicon-containing conductive film, and (b) supplying, into the chamber, a processing gas that contains a bromine containing gas, a phosphorus fluoride gas, and an oxygen containing gas, and generating a plasma from the processing gas to etch the silicon film or the silicon-containing conductive film.

In one exemplary embodiment, the silicon-containing conductive film is a film containing silicon and germanium or a metal.

In one exemplary embodiment, the mask includes at least one selected from the group consisting of a silicon-containing insulating film, a metal-containing film, and an organic film.

In one exemplary embodiment, in (b), a ratio of a flow rate of the phosphorus fluoride gas to a flow rate of the processing gas is changed.

In one exemplary embodiment, (b) includes (b1) etching the silicon film or the silicon-containing conductive film with a first plasma generated from a first processing gas that contains a phosphorus fluoride gas at a first flow ratio, and (b2) etching the silicon film or the silicon-containing conductive film with a second plasma generated from a second processing gas that does not contain a phosphorus fluoride gas or contains a phosphorus fluoride gas at a second flow ratio smaller than the first flow ratio.

In one exemplary embodiment, (b2) is performed after (b1).

In one exemplary embodiment, (b1) is performed after (b2).

In one exemplary embodiment, (b1) and (b2) are repeated a plurality of times.

In one exemplary embodiment, a flow rate of the bromine containing gas is larger than a flow rate of the phosphorus fluoride gas.

In one exemplary embodiment, a flow rate of the bromine containing gas is 10 vol % or more and 99 vol % or less of a flow rate of the processing gas.

In one exemplary embodiment, a flow rate of the phosphorus fluoride gas is 0.1 vol % or more and 50 vol % or less of a flow rate of the processing gas.

In one exemplary embodiment, a ratio of a flow rate of the bromine containing gas to a flow rate of the phosphorus fluoride gas is in a range of 1 to 999.

In one exemplary embodiment, the bromine containing gas is at least one of an HBr gas and a Br₂ gas.

In one exemplary embodiment, the phosphorus fluoride gas is at least one of a PF₃ gas and a PF₅ gas.

In one exemplary embodiment, the oxygen containing gas is at least one selected from the group consisting of an O₂ gas, a CO gas, and a CO₂ gas.

In one exemplary embodiment, an etching method is provided, which includes: (a) providing, on a substrate support disposed in a chamber, a substrate that includes a silicon film or a silicon-containing conductive film and a mask on the silicon film or the silicon-containing conductive film, and (b) supplying, into the chamber, a processing gas containing a first gas that contains a first halogen, a second gas that contains a second halogen and phosphorus, and an oxygen containing gas, and generating a plasma from the processing gas to etch the silicon film or the silicon-containing conductive film.

In one exemplary embodiment, the silicon-containing conductive film is a film containing silicon and germanium or a metal.

In one exemplary embodiment, in (b), a ratio of a flow rate of the second gas to a flow rate of the processing gas is changed.

In one exemplary embodiment, the mask includes at least one selected from the group consisting of a silicon-containing insulating film, a metal-containing film, and an organic film.

In one exemplary embodiment, the mask contains at least one selected from the group consisting of silicon oxide, SiON, W, WSi, WSIN, WC, TiN, and TiO.

In one exemplary embodiment, the first gas is at least one selected from the group consisting of an HBr gas, a Br₂ gas, and a Cl₂ gas.

In one exemplary embodiment, the second gas is at least one selected from the group consisting of a PF₃ gas, a PF₅ gas, and a PCl₃ gas.

In one exemplary embodiment, there is provided a plasma processing apparatus, which includes: a chamber, a substrate support disposed in the chamber, a plasma generator, and a controller, the controller executing (a) control to provide, on the substrate support, a substrate that includes a silicon film or a silicon-containing conductive film and a mask on the silicon film or the silicon-containing conductive film, and (b) control to supply, into the chamber, a processing gas that contains a bromine containing gas, a phosphorus fluoride gas, and an oxygen containing gas, and generate a plasma from the processing gas to etch the silicon film or the silicon-containing conductive film.

An embodiment of the present disclosure will be described below in detail with reference to the drawings. In the drawings, the same or similar elements have the same reference characters, and duplicated descriptions thereof will be omitted. Unless otherwise specified, the upward-downward positional relationship, the rightward/leftward positional relationship, and other positional relationship will be described based on the positional relationships shown in the drawings. The dimensional ratios in the drawings are not equal to actual ratios, and the actual ratios are not limited to the ratios shown in the drawings.

### <Example of Plasma Processing System>

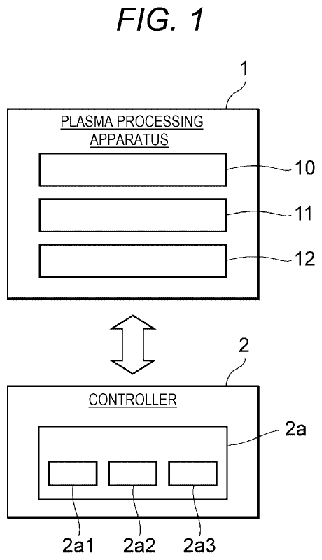

FIG. 1 is a diagram illustrating an example of a configuration of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. The plasma processing chamber 10 has at least one gas supply port via which at least one processing gas is supplied into the plasma processing space, and at least one gas exhaust port via which the gas is exhausted from the plasma processing space. The gas supply port is connected to a gas supply 20, which will be described later, and the gas exhaust port is connected to an exhaust system 40, which will be described later. The substrate support 11 is disposed in the plasma processing space and has a substrate support surface for supporting a substrate.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), surface wave plasma (SWP), or the like. Furthermore, various types of plasma generators, including an alternating current (AC) plasma generator and a direct current (DC) plasma generator, may be used. In one embodiment, an AC signal (AC power) used by the AC plasma generator has a frequency within a range from 100 kHz to 10 GHz. The AC signal therefore includes a radio frequency (RF) signal and a microwave signal. In one embodiment, the RF signal has a frequency within a range from 100 kHz to 150 MHz.

The controller 2 processes computer-executable instructions for instructing the plasma processing apparatus 1 to execute various steps described herein below. The controller 2 may be configured to control elements of the plasma processing apparatus 1 to execute the various steps described herein below. In one embodiment, part or all of the controller 2 may be in the plasma processing apparatus 1. The controller 2 may include, for example, a computer 2a. For example, the computer 2a may include a processor (central processing unit (CPU)) 2a1, a storage 2a2, and a communication interface 2a3. The processor 2al may be configured to read a program from the storage 2a2 and perform various control operations by executing the read program. The program may be stored in advance in the storage 2a2, or may be acquired via a medium when necessary. The acquired program is stored in the storage 2a2, read from the storage 2a2 by the processor 2al, and executed thereby. The medium may be various storing media readable by the computer 2a, or may be a communication line connected to the communication interface 2a3. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN). The functionality of the elements disclosed herein may be implemented using circuitry or processing circuitry which includes general purpose processors, special purpose processors, integrated circuits, ASICs (“Application Specific Integrated Circuits”), FPGAs (“Field-Programmable Gate Arrays”), conventional circuitry and/or combinations thereof which are programmed, using one or more programs stored in one or more memories, or otherwise configured to perform the disclosed functionality. Processors and controllers are considered processing circuitry or circuitry as they include transistors and other circuitry therein. In the disclosure, the circuitry, units, or means are hardware that carry out or are programmed to perform the recited functionality. The hardware may be any hardware disclosed herein which is programmed or configured to carry out the recited functionality. There is a memory that stores a computer program which includes computer instructions. These computer instructions provide the logic and routines that enable the hardware (e.g., processing circuitry or circuitry) to perform the method disclosed herein. This computer program can be implemented in known formats as a computer-readable storage medium, a computer program product, a memory device, a record medium such as a CD-ROM or DVD, and/or the memory of a FPGA or ASIC.

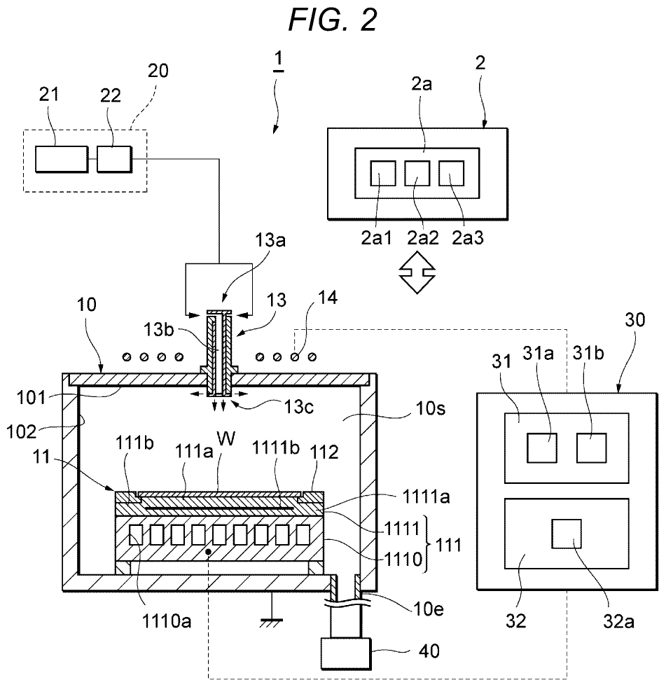

Hereinafter, a configuration example of an inductively coupled plasma processing apparatus as an example of the plasma processing apparatus 1 will be described. FIG. 2 is a diagram illustrating the configuration example of the inductively coupled plasma processing apparatus. The inductively coupled plasma processing apparatus 1 includes the plasma processing chamber 10, the gas supply 20, a power source 30, and the exhaust system 40. The plasma processing chamber 10 includes a dielectric window 101. Further, the plasma processing apparatus 1 includes the substrate support 11, a gas introduction unit, and an antenna 14. The substrate support 11 is disposed in the plasma processing chamber 10. The antenna 14 is disposed on or above the plasma processing chamber 10 (that is, on or above the dielectric window 101). The plasma processing chamber 10 has a plasma processing space 10s defined by the dielectric window 101, a sidewall 102 of the plasma processing chamber 10, and the substrate support 11. The plasma processing chamber 10 is grounded.

The substrate support 11 includes a main body 111 and a ring assembly 112. The main body 111 has a central region 111a, which supports a substrate W, and an annular region 111b, which supports the ring assembly 112. A wafer is an example of the substrate W. The annular region 111b of the main body 111 surrounds the central region 111a of the main body 111 in a plan view. The substrate W is disposed on the central region 111a of the main body 111, and the ring assembly 112 is disposed on the annular region 111b of the main body 111 so as to surround the substrate W on the central region 111a of the main body 111. Accordingly, the central region 111a is also called a substrate support surface that supports the substrate W, and the annular region 111b is also called a ring support surface that supports the ring assembly 112.

In one embodiment, the main body 111 includes a base 1110 and an electrostatic chuck 1111. The base 1110 includes a conductive member. The conductive member of the base 1110 may function as a bias electrode. The electrostatic chuck 1111 is disposed on the base 1110. The electrostatic chuck 1111 includes a ceramic member 1111a, and an electrostatic electrode 1111b disposed in the ceramic member 1111a. The ceramic member 1111a has the central region 111a. In one embodiment, the ceramic member 1111a also has the annular region 111b. Another member that surrounds the electrostatic chuck 1111, such as an annular electrostatic chuck and an annular insulating member, may have the annular region 111b. In this case, the ring assembly 112 may be disposed on the annular electrostatic chuck or the annular insulating member, or may be disposed on both the electrostatic chuck 1111 and the annular insulating member. Further, an RF or DC electrode may be disposed in the ceramic member 1111a, and in this case, the RF or DC electrode functions as a bias electrode. Both the conductive member of the base 1110 and the RF or DC electrode may function as the two bias electrodes.

The ring assembly 112 includes one or more annular members. In one embodiment, the one or more annular members include one or more edge rings and at least one cover ring. The edge ring is made of an electrically conductive material or an insulating material, and the cover ring is made of an insulating material.

The substrate support 11 may further include a temperature control module configured to adjust a temperature of at least one of the electrostatic chuck 1111, the ring assembly 112, and the substrate W to a target temperature. The temperature control module may include a heater, a heat transfer medium, a flow path 1110a, or a combination thereof. A heat transfer fluid, such as brine or gas, flows through the flow path 1110a. In one embodiment, the flow path 1110a is formed in the base 1110, and one or more heaters are disposed in the ceramic member 1111a of the electrostatic chuck 1111. Further, the substrate support 11 may include a heat transfer gas supply configured to supply a heat transfer gas to a gap between a rear surface of the substrate W and the central region 111a.

The gas introduction unit is configured to introduce at least one processing gas from the gas supply 20 into the plasma processing space 10s. In one embodiment, the gas introduction unit includes a center gas injector (CGI) 13. The center gas injector 13 is disposed above the substrate support 11 and attached to a center opening formed in the dielectric window 101. The center gas injector 13 has at least one gas supply port 13a, at least one gas flow path 13b, and at least one gas introduction port 13c. The processing gas supplied to the gas supply port 13a passes through the gas flow path 13b and is introduced into the plasma processing space 10s from the gas introduction port 13c. The gas introduction unit may include one or more side gas injectors (SGI) attached to one or more openings formed in the sidewall 102, in addition to or instead of the center gas injector 13.

The gas supply 20 may include at least one gas source 21 and at least one flow rate controller 22. In one embodiment, the gas supply 20 is configured to supply at least one processing gas from the respective corresponding gas sources 21 to the gas introduction unit through the respective corresponding flow rate controllers 22. Each flow rate controller 22 may include, for example, a mass flow controller or a pressure-controlled flow rate controller. Further, the gas supply 20 may include at least one flow rate modulation device that modulates or pulses a flow rate of at least one processing gas.

The power source 30 includes an RF power source 31 coupled to the plasma processing chamber 10 via at least one impedance matching circuit. The RF power source 31 is configured to supply at least one RF signal (RF power), such as a source RF signal and a bias RF signal, to at least one bias electrode and the antenna 14. Accordingly, the plasma is formed from at least one processing gas supplied into the plasma processing space 10s.

Accordingly, the RF power source 31 may function as at least a part of the plasma generator 12. Supplying the bias RF signal to at least one bias electrode can generate a bias potential in the substrate W to attract ions in the formed plasma to the substrate W.

In one embodiment, the RF power source 31 includes a first RF generator 31a and a second RF generator 31b. The first RF generator 31a is configured to be coupled to the antenna 14 through at least one impedance matching circuit so as to generate the source RF signal (source RF power) for plasma generation. In one embodiment, the source RF signal has a frequency within a range from 10 MHz to 150 MHz. In one embodiment, the first RF generator 31a may be configured to generate a plurality of source RF signals having different frequencies. The generated one or more source RF signals are supplied to the antenna 14.

The second RF generator 31b is coupled to at least one bias electrode via the at least one impedance matching circuit and configured to generate the bias RF signal (bias RF power). A frequency of the bias RF signal may be the same as or different from a frequency of the source RF signal. In one embodiment, the bias RF signal has a frequency lower than the frequency of the source RF signal. In one embodiment, the bias RF signal has a frequency within a range from 100 kHz to 60 MHz. In one embodiment, the second RF generator 31b may be configured to generate a plurality of bias RF signals having different frequencies. The generated one or more bias RF signals are supplied to at least one bias electrode. In various embodiments, at least one of the source RF signal and the bias RF signal may be pulsed.

The power source 30 may include a DC power source 32 coupled to the plasma processing chamber 10. The DC power source 32 includes a bias DC generator 32a. In one embodiment, the bias DC generator 32a is connected to at least one bias electrode and configured to generate a bias DC signal. The generated bias DC signal is applied to at least one bias electrode.

In various embodiments, the bias DC signal may be pulsed. In this case, a sequence of DC-based voltage pulses is applied to at least one bias electrode. The voltage pulses may each have a rectangular, trapezoidal, or triangular pulse waveform or a combination thereof. In one embodiment, a waveform generator for generating the sequence of voltage pulses from the DC signal is connected between the bias DC generator 32a and at least one bias electrode. Accordingly, the bias DC generator 32a and the waveform generator configure a voltage pulse generator. The voltage pulse may have a positive polarity or a negative polarity. Further, the sequence of the voltage pulses may include one or more positive voltage pulses and one or more negative voltage pulses in one cycle. The bias DC generator 32a may be provided in addition to the RF power source 31, or may be provided instead of the second RF generator 31b.

The antenna 14 includes one or more coils. In one embodiment, the antenna 14 may include an outer coil and an inner coil that are coaxially disposed. In this case, the RF power source 31 may be connected to both the outer coil and the inner coil, or may be connected to any one of the outer coil and the inner coil. In the former case, the same RF generator may be connected to both the outer coil and the inner coil, or separate RF generators may be connected to the outer coil and the inner coil, respectively.

The exhaust system 40 may be connected, for example, to a gas exhaust port 10e disposed at a bottom of the plasma processing chamber 10. The exhaust system 40 may include a pressure adjusting valve and a vacuum pump. The pressure adjusting valve adjusts a pressure in the plasma processing space 10s. The vacuum pump may include a turbo molecular pump, a dry pump, or a combination thereof.

### Examples of Etching Method

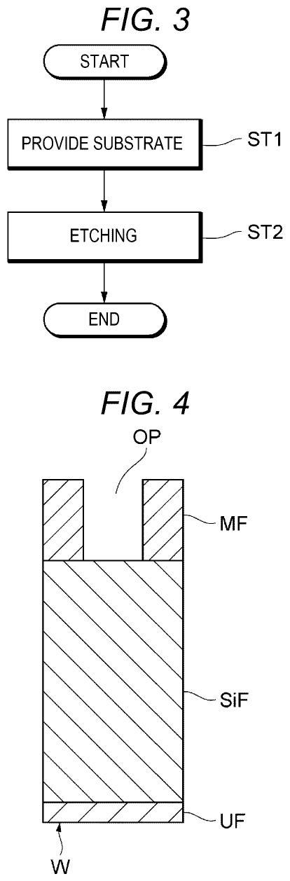

FIG. 3 is a flowchart illustrating an etching method (hereinafter, also referred to as a “present processing method”) according to one exemplary embodiment. As shown in FIG. 3, in one embodiment, the present processing method includes step ST1 of providing a substrate, and step ST2 of performing etching. Processing in each of the steps may be executed by the plasma processing system illustrated in FIG. 2. Hereinafter, a case where the controller 2 controls each part of the plasma processing apparatus 1 to execute the present processing method for the substrate W will be described by way of an example.

### Step ST1: Provision of Substrate

In step ST1, the substrate W is provided into the plasma processing space 10s of the plasma processing apparatus 1. In one embodiment, the substrate W is provided in the central region 111a of the substrate support 11. Then, the substrate Wis held by the substrate support 11 by the electrostatic chuck 1111.

FIG. 4 is a diagram illustrating an example of a cross-sectional structure of the substrate W. In the substrate W, a silicon film SiF and a mask MF are stacked in this order on or above an underlying film UF. The substrate W may be used for manufacturing a semiconductor device. The semiconductor device includes, for example, a semiconductor memory device such as a DRAM or a 3D-NAND flash memory and a logic device.

The underlying film UF is, in an example, a silicon wafer, or an organic film, a dielectric film, a metal-containing film, a semiconductor film, or the like formed on the silicon wafer. The underlying film UF may be configured by stacking a plurality of films.

The silicon film SiF is a film that is an etching target in the present processing method. The silicon film SiF may be any of a polycrystalline silicon film, a single crystal silicon film, and an amorphous silicon film. The silicon film SiF may contain impurities such as phosphorus, boron, and nitrogen.

The mask MF is a film that functions as a mask in the etching of the silicon film SiF. The mask MF may be a film different from an etching target film. The mask MF may be at least one selected from the group consisting of a silicon-containing insulating film, a metal-containing film, and an organic film. The silicon-containing insulating film may be a silicon oxide film, a silicon nitride film, or a silicon oxynitride (SiON) film. The metal-containing film may be a film containing tungsten (W), titanium (Ti), or ruthenium (Ru). The mask MF may contain at least one selected from the group consisting of tungsten (W), tungsten silicide (WSi), tungsten silicide nitride (WSiN), tungsten carbide (WC), tungsten silicide carbide (WSiC), titanium nitride (TiN), titanium oxide (TiO), ruthenium (Ru), ruthenium carbide (RuC), ruthenium nitride (RuN), and ruthenium silicide (RuSi). The organic film may be an amorphous carbon film or a spin-on carbon film. In one embodiment, the mask MF contains at least one selected from the group consisting of silicon oxide, SiON, W, WSi, WSIN, WC, TiN, and TiO.

As illustrated in FIG. 4, the mask MF defines at least one opening OP on the silicon film SiF. The opening OP is a space on the silicon film SiF and is surrounded by a sidewall of the mask MF. That is, an upper surface of the silicon film SiF has a region covered with the mask MF and a region exposed at a bottom of the opening OP.

The opening OP may have any shape in a plan view of the substrate W, that is, when the substrate W is viewed in a downward direction from above in FIG. 4. The shape may be, for example, a circle, an ellipse, a rectangle, a line, or a shape obtained by combining one or more types thereof. The mask MF may have a plurality of sidewalls, and the plurality of sidewalls may define a plurality of openings OP. The plurality of openings OP may each have a linear shape, and may be arranged at regular intervals to form a line and space pattern. Further, the plurality of openings OP may each have a hole shape and may form an array pattern.

Each of the films (the underlying film UF, the silicon film SiF, and the mask MF) constituting the substrate W may be formed by a CVD method, an ALD method, a spin coating method, or the like. The opening OP may be formed by etching the mask MF. Further, the mask MF may be formed by lithography. Each of the above-described films may be a flat film or a film having unevenness. The substrate W may further have another film below the underlying film UF, and a stacked film containing the silicon film SiF and the underlying film UF may function as a multilayer mask. That is, the other film may be etched using the stacked film of the silicon film SiF and the underlying film UF as the multilayer mask.

At least a part of processes of forming the films of the substrate W may be performed in a space of the plasma processing chamber 10 illustrated in FIG. 2. In an example, a step of etching the mask MF to form the opening OP may be executed in the plasma processing chamber 10. That is, the etching of the opening OP and the silicon film SiF, which will be described later, may be consecutively executed in the same chamber. Further, the substrate may be provided by forming all or some of the respective films of the substrate W with an apparatus or a chamber outside the plasma processing apparatus 1, and then carrying the substrate W into the plasma processing space 10s of the plasma processing apparatus 1 and disposing the substrate W on the central region 111a of the substrate support 11.

In one embodiment, after the substrate W is provided in the central region 111a of the substrate support 11, a temperature of the substrate support 11 is adjusted to a set temperature by the temperature control module. The temperature of the substrate support 11 is set to, for example, a range of 10° C. or higher and 120° C. or lower. In an example, adjusting or maintaining the temperature of the substrate support 11 includes adjusting or maintaining the temperature of the heat transfer fluid flowing through the flow path 1110a to the set temperature or a temperature different from the set temperature. In an example, adjusting or maintaining the temperature of the substrate support 11 includes controlling the pressure of a heat transfer gas (for example, He) between the electrostatic chuck 1111 and the rear surface of the substrate W. The time at which the heat transfer fluid starts to flow through the flow path 1110a may be before or after the substrate W is placed on the substrate support 11, or may be at the same time. Further, in the present processing method, the temperature of the substrate support 11 may be adjusted to the set temperature before step ST1. That is, after the temperature of the substrate support 11 is adjusted to the set temperature, the substrate W may be provided to the substrate support 11. In steps subsequent to step ST1, the temperature of the substrate support 11 may be maintained at the set temperature adjusted in step ST1. The temperature of the substrate W on the substrate support 11 may be adjusted to, for example, a range of 10° C. or higher and 250° C. or lower. The adjustment or maintenance of the temperature of the substrate W may be performed by adjusting the temperature of the substrate support 11 described above.

### (Step ST2: Etching)

In step ST2, first, a processing gas is supplied from the gas supply 20 into the plasma processing space 10s. The processing gas may contain a bromine containing gas, a phosphorus fluoride gas, and an oxygen containing gas. A flow rate of the bromine containing gas may be the largest with respect to a total flow rate of the processing gas. Flow rates of the bromine containing gas, the phosphorus fluoride gas, and the oxygen containing gas may be 30 vol % or more, 50 vol % or more, 60 vol % or more, and 70 vol % or more with respect to the total flow rate of the processing gas. The processing gas may be free of a fluorine containing gas other than phosphorus fluoride. The processing gas may not contain a hydrogen fluoride gas, may not contain a fluorocarbon gas, or may not contain a hydrofluorocarbon gas.

The flow rate of the bromine containing gas may be larger than the flow rate of the phosphorus fluoride gas. The flow rate of the bromine containing gas may be 10 vol % or more and 99 vol % or less of the flow rate of the processing gas (when the processing gas contains another gas such as an inert gas, the flow rate excluding the other gas). The flow rate of the bromine containing gas may be 30 vol % or more or 50 vol % or more of the flow rate of the processing gas. The flow rate of the bromine containing gas may be 95 vol % or less or 90 vol % or less of the flow rate of the processing gas. The flow rate of the phosphorus fluoride gas may be 0.1 vol % or more and 50 vol % or less of the flow rate of the processing gas. The flow rate of the phosphorus fluoride gas may be 1 vol % or more, 2 vol % or more, or 3 vol % or more of the flow rate of the processing gas. The flow rate of the phosphorus fluoride gas may be 30 vol % or less, 20 vol % or less, 10 vol % or less, or 5 vol % or less of the flow rate of the processing gas. A ratio of the flow rate of the bromine containing gas to the flow rate of the phosphorus fluoride gas (the flow rate of the bromine containing gas/the flow rate of the phosphorus fluoride gas) may be in a range of 1 to 999.

The bromine containing gas may be at least one of an HBr gas, a Br₂ gas, a CBr₂F₂ gas, and an S₂Br₂ gas, and may be at least one of an HBr gas and a Br₂ gas.

The phosphorus fluoride gas is a gas containing fluorine and phosphorus, and in one example, may be at least one selected from the group consisting of a PF₃ gas, a PF₅ gas, a POF₃ gas, an HPF₂ gas, an H₂PF₃ gas, and an HPF gas. In one example, the phosphorus fluoride gas may be at least one gas of the PF₃ gas and the PF₅ gas.

The oxygen containing gas may be, for example, at least one selected from the group consisting of an O₂ gas, a CO gas, a CO₂ gas, an H₂O gas, and an H₂O₂ gas. In one example, the oxygen containing gas may be an oxygen containing gas other than the H₂O gas and the H₂O₂ gas, for example, may be at least one selected from the group consisting of the O₂ gas, the CO gas, and the CO₂ gas.

The processing gas may further contain an inert gas. The inert gas may be, in one example, a rare gas such as an Ar gas, a He gas, or a Kr gas, or a nitrogen gas.

The processing gas may contain a gas containing another halogen different from bromine, instead of or in addition to the bromine containing gas. In one example, the processing gas may include a Cl₂ gas.

The processing gas may contain a gas containing phosphorus and another halogen different from fluorine, instead of or in addition to the phosphorus fluoride gas. In one example, the processing gas may contain a PCl₃ gas.

In step ST2, next, a plasma is generated from the processing gas, and the silicon film SiF is etched using the plasma. First, the source RF signal is supplied to the antenna 14. In this way, a radio-frequency electric field is generated between the antenna 14 and the substrate support 11, so that plasma is generated from the processing gas in the plasma processing space 10s. At this time, the bias signal may be supplied to the bias electrode of the substrate support 11. In this case, a bias potential is generated between the plasma and the substrate W. Active species such as ions and radicals in the plasma are attracted to the substrate W, and the silicon film SiF is etched by the active species. The bias signal may be a bias RF signal supplied from the RF power source 31 or a bias DC signal supplied from the DC power source 32.

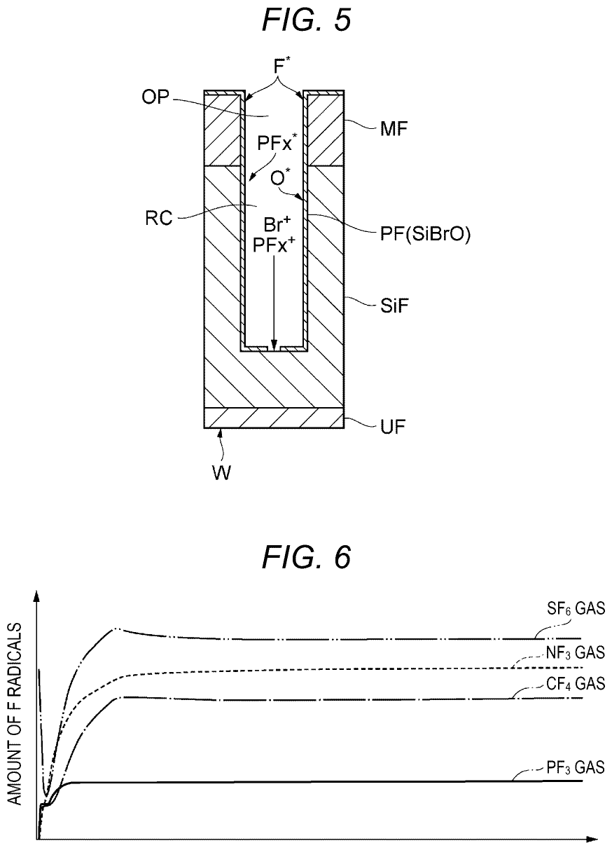

FIG. 5 is a diagram illustrating an example of a cross-sectional structure of the substrate W during processing of step ST2. As shown in FIG. 5, a portion of the silicon film SiF exposed in the opening OP is etched in a depth direction (a downward direction from above in FIG. 5) by the processing in step ST2, so that a recess RC is formed. A protective film PF is formed on a sidewall of the recess RC and a surface of the mask MF.

In the present processing method, the processing gas contains at least a bromine containing gas, a phosphorus fluoride gas, and an oxygen containing gas. The active species generated from the bromine containing gas mainly function as an etchant for removing the silicon film SiF. The active species generated from the oxygen containing gas have a function of adjusting an amount of by-products (the protective film PF) that are deposited on the sidewall of the recess RC and the surface of the mask MF. The active species generated from the phosphorus fluoride gas have a function of reducing by-products (the protective film PF) that are deposited near the opening OP of the mask MF.

In one example, bromine ions (Br⁺) derived from the bromine containing gas and oxygen radicals (O*) derived from the oxygen containing gas form the protective film PF containing a silicon-based by-product (SiBrO) on the sidewall of the recess RC and the surface of the mask MF. In one example, phosphorus fluoride ions (PFx⁺) derived from the phosphorus fluoride gas remove by-products (excessive protective film PF) that are deposited near the opening OP of the mask MF. Accordingly, it is possible to prevent a vicinity of the opening OP of the mask MF from being blocked or narrowed. Since the phosphorus fluoride gas is less likely to dissociate and an amount of the F radicals (F*) is small, scraping (bowing) of the sidewall of the recess RC is prevented. In one example, the phosphorus fluoride ions (PFx⁺) derived from the phosphorus fluoride gas remove the protective film PF formed at a bottom of the recess RC. Accordingly, the silicon film SiF at the bottom of the recess RC is exposed, and the etching of the silicon film SiF in the depth direction is promoted by the bromine ions (Br⁺). In an example, by-products are deposited on the sidewall of the recess RC by a phosphorus component such as a phosphorus fluoride radical (PFx*) derived from the phosphorus fluoride gas. Accordingly, the sidewall of the recess RC is prevented from being scraped (bowing), and etching selectivity is improved.

According to the present exemplary embodiment, the etching method includes: step (ST1) of providing the substrate W that includes the silicon film SiF and the mask MF on the silicon film SiF on the substrate support 11 in the chamber 10, and the mask MF includes the silicon oxide, and the step (ST2) of supplying the processing gas that contains a bromine containing gas, a phosphorus fluoride gas, and an oxygen containing gas into the chamber 10, and generating a plasma from the processing gas to etch the silicon film SiF. Accordingly, since the vicinity of the opening OP of the mask MF is prevented from narrowing and the sidewall of the recess RC of the silicon film SiF is prevented from being scraped, shape abnormalities due to etching of the silicon film SiF can be prevented.

### Examples

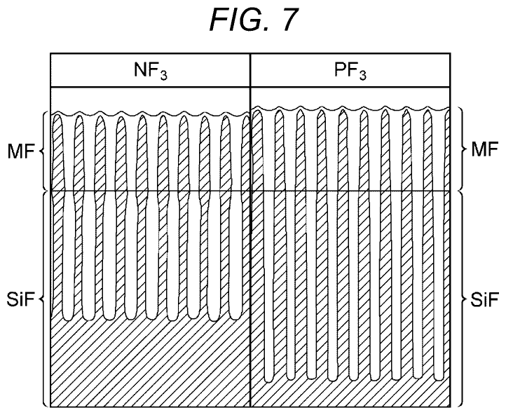

FIG. 6 is a diagram illustrating an amount of F radicals generated when a plasma is generated using various gases. In an experiment, the plasma was generated using a processing gas that contained an SF₆ gas, an NF₃ gas, a CF₄ gas, or a PF₃ gas, and the amount of F radicals generated was measured by an optical emission spectrometer. As shown in FIG. 6, when the PF₃ gas was used, the amount of F radicals generated was small. Ionization energy of the PF₃ gas is lower than ionization energy of the NF₃ gas, and the PF₃ gas is easily ionized. Therefore, it can be seen that in the plasma generated from the processing gas that contains the PF₃ gas, the amount of F radicals is smaller, and an amount of phosphorus fluoride ions is larger, resulting in a smaller ratio of radicals/ions, than that in the plasma generated from the processing gas that contains the NF₃ gas. Due to the small amount of F radicals, the excessive protective film PF near the opening OP is removed, while the protective film PF on the sidewall of the recess RC located deeper than the opening OP is prevented from being scraped. Due to the large amount of the phosphorus fluoride ions, the phosphorus fluoride ions etch the protective film PF formed at the bottom of the recess RC to expose the silicon film SiF, so that the bromine ions can reach the silicon film SiF. Accordingly, it is possible to promote the etching of the silicon film SiF in the depth direction.

FIG. 7 illustrates results of etching the silicon film SiF when the PF₃ gas and the NF₃ gas are used as a part of the processing gas. FIG. 7 is a diagram schematically illustrating an image obtained by capturing an image of the etched silicon film SiF by a scanning electron microscope. The etching was performed at a set temperature of the substrate support of 60° C., and the flow rates of the various gases were set to flow ratios shown in Table 1.

TABLE 1

| | When PF₃ is used | When NF₃ is used |
|---|---|---|
| HBr (vol %) | 80.6 | 74.0 |
| O₂ (vol %) | 3.0 | 2.7 |
| Ar (vol %) | 14.9 | 13.7 |
| PF₃ (vol %) | 1.5 | 0 |
| NF₃ (vol %) | 0 | 9.6 |
| HBr/PF₃ | 54 | 0 |

When the PF₃ gas was used, there was no deposit near the opening OP of the mask MF that blocks the opening. As a result of measuring dimensions of line widths at an upper portion, a middle portion, and a lower portion of the silicon film SiF for each of the cases where the NF₃ gas and the PF₃ gas were used, it was confirmed that when the PF₃ gas was used, there was less deviation in the dimensions of the line width of the silicon film SiF than when the NF₃ gas was used, and the shape abnormalities were prevented. As a result of calculating an etching rate (ER) for each of the cases where the NF₃ gas and the PF₃ gas were used, it was confirmed that the etching rate was improved when the PF₃ gas was used compared with when the NF₃ gas was used. As a result of measuring a depth of a hole in the silicon film SiF and a thickness of the mask for each of the cases where the NF₃ gas and the PF₃ gas were used, it was confirmed that etching selectivity was improved when the PF₃ gas was used than when the NF₃ gas was used.

In the embodiment described above, in the etching step ST2, a ratio of the flow rate of the phosphorus fluoride gas to the flow rate of the processing gas may be changed. In one embodiment, the ratio (Ra) of the flow rate of the phosphorus fluoride gas to the flow rate of the processing gas may be changed according to a depth of the recess RC of the silicon film SiF. In one embodiment, the ratio (Ra) of the flow rate of the phosphorus fluoride gas may be increased as the recess RC of the silicon film SiF becomes deeper. The ratio (Ra) of the flow rate of the phosphorus fluoride gas may be reduced as the recess RC of the silicon film SiF becomes deeper. In one embodiment, the etching step ST2 may include a first etching step ST21 and a second etching step ST22. The first etching step ST21 is a step of etching the silicon film SiF with a first plasma generated from a first processing gas that contains the phosphorus fluoride gas at a first flow ratio. The second etching step ST22 is a step of etching the silicon film SiF with a second plasma generated from a second processing gas that does not contain the phosphorus fluoride gas or contains the phosphorus fluoride gas at a second flow ratio smaller than the first flow ratio. The second etching step ST22 may be performed after the first etching step ST21, the first etching step ST21 may be performed after the second etching step ST22, and the first etching step ST21 and the second etching step ST22 may be repeated a plurality of times. The first processing gas may be the processing gas described in the above embodiment, which contains the bromine containing gas, the phosphorus fluoride gas, and the oxygen containing gas. The second processing gas may be the processing gas that contains the bromine containing gas, the phosphorus fluoride gas, and the oxygen containing gas described in the above embodiment, or may be the processing gas that contains the bromine containing gas and the oxygen containing gas and does not contain phosphorus fluoride.

In the embodiment described above, the etching step ST2 may include a first period in which the phosphorus fluoride gas is not supplied, and a second period in which the phosphorus fluoride gas is supplied. In one embodiment, in the first period of the etching step ST2, the plasma may be generated from the processing gas that contains the bromine containing gas and the oxygen containing gas to etch the silicon film SiF, and thereafter, in the second period, the plasma may be generated from the processing gas that contains the bromine containing gas, the oxygen containing gas, and the phosphorus fluoride gas to etch the silicon film SiF. The first period and the second period may be alternately repeated.

In the embodiment described above, the etching target film is a silicon film. However, the etching target film may be a silicon-containing conductive film. The silicon-containing conductive film may be a film containing silicon and germanium, or a film containing silicon and a metal. That is, the silicon-containing conductive film may be SiGe or a metal silicide such as WSi.

In the embodiment described above, the present processing method is not limited to be performed by the inductively coupled plasma processing apparatus, and may be performed by another type of plasma processing apparatus, for example, a plasma processing apparatus that generates a capacitively coupled plasma, a plasma processing apparatus that generates an ECR plasma, a plasma processing apparatus that generates a helicon wave plasma, or a plasma processing apparatus that generates a surface wave plasma.

The present disclosure may include, for example, following configurations.

### Appendix 1

An etching method including:
(a) providing, on a substrate support disposed in a chamber, a substrate that includes a silicon film or a silicon-containing conductive film and a mask on the silicon film or the silicon-containing conductive film, and
(b) supplying, into the chamber, a processing gas that contains a bromine containing gas, a phosphorus fluoride gas, and an oxygen containing gas, and generating a plasma from the processing gas to etch the silicon film or the silicon-containing conductive film.

### Appendix 2

The etching method according to Appendix 1, in which the silicon-containing conductive film is a film containing silicon and germanium or a metal.

### Appendix 3

The etching method according to Appendix 1 or 2, in which the mask includes at least one selected from the group consisting of a silicon-containing insulating film, a metal-containing film, and an organic film.

### Appendix 4

The etching method according to any one of Appendixes 1 to 3, in which in (b), a ratio of a flow rate of the phosphorus fluoride gas to a flow rate of the processing gas is changed.

### Appendix 5

The etching method according to any one of Appendixes 1 to 4, in which
(b) includes
   (b1) etching the silicon film or the silicon-containing conductive film with a first plasma generated from a first processing gas that contains a phosphorus fluoride gas at a first flow ratio, and
   (b2) etching the silicon film or the silicon-containing conductive film with a second plasma generated from a second processing gas that does not contain a phosphorus fluoride gas or contains a phosphorus fluoride gas at a second flow ratio smaller than the first flow ratio.

### Appendix 6

The etching method according to Appendix 5, in which
(b2) is performed after (b1).

### Appendix 7

The etching method according to Appendix 5, in which
(b1) is performed after (b2).

### Appendix 8

The etching method according to any one of Appendixes 5 to 7, in which
(b1) and (b2) are repeated a plurality of times.

### Appendix 9

The etching method according to any one of Appendixes 1 to 8, in which
a flow rate of the bromine containing gas is larger than a flow rate of the phosphorus fluoride gas.

### Appendix 10

The etching method according to any one of Appendixes 1 to 9, in which
a flow rate of the bromine containing gas is 10 vol % or more and 99 vol % or less of a flow rate of the processing gas.

### Appendix 11

The etching method according to any one of Appendixes 1 to 10, in which
a flow rate of the phosphorus fluoride gas is 0.1 vol % or more and 50 vol % or less of a flow rate of the processing gas.

### Appendix 12

The etching method according to any one of Appendixes 1 to 11, in which
a ratio of a flow rate of the bromine containing gas to a flow rate of the phosphorus fluoride gas is in a range of 1 to 999.

### Appendix 13

The etching method according to any one of Appendixes 1 to 12, in which
the bromine containing gas is at least one of an HBr gas and a Br₂ gas.

### Appendix 14

The etching method according to any one of Appendixes 1 to 13, in which
the phosphorus fluoride gas is at least one of a PF₃ gas and a PF₅ gas.

### Appendix 15

The etching method according to any one of Appendixes 1 to 14, in which
the oxygen containing gas is at least one selected from the group consisting of an O₂ gas, a CO gas, and a CO₂ gas.

### Appendix 16

An etching method including:
(a) providing, on a substrate support disposed in a chamber, a substrate that includes a silicon film or a silicon-containing conductive film and a mask on the silicon film or the silicon-containing conductive film, and
(b) supplying, into the chamber, a processing gas containing a first gas that contains a first halogen, a second gas that contains a second halogen and phosphorus, and an oxygen containing gas, and generating a plasma from the processing gas to etch the silicon film or the silicon-containing conductive film.

### Appendix 17

The etching method according to Appendix 16, in which
the silicon-containing conductive film is a film containing silicon and germanium or a metal.

### Appendix 18

The etching method according to Appendix 16 or 17, in which
in (b), a ratio of a flow rate of the second gas to a flow rate of the processing gas is changed.

### Appendix 19

The etching method according to any one of Appendixes 16 to 18, in which
the mask includes at least one selected from the group consisting of a silicon-containing insulating film, a metal-containing film, and an organic film.

### Appendix 20

The etching method according to any one of Appendixes 16 to 19, in which
the mask contains at least one selected from the group consisting of silicon oxide, SiON, W, WSi, WSIN, WC, TiN, and TiO.

### Appendix 21

The etching method according to any one of Appendixes 16 to 20, in which
the first gas is at least one selected from the group consisting of an HBr gas, a Br₂ gas, and a Cl₂ gas.

### Appendix 22

The etching method according to any one of Appendixes 16 to 21, in which
the second gas is at least one selected from the group consisting of a PF₃ gas, a PF₅ gas, and a PCl₃ gas.

### Appendix 23

A plasma processing apparatus including:
a chamber,
a substrate support disposed in the chamber,
a plasma generator, and
a controller, the controller executing (a) control to provide, on the substrate support, a substrate that includes a silicon film or a silicon-containing conductive film and a mask on the silicon film or the silicon-containing conductive film, and (b) control to supply, into the chamber, a processing gas that contains a bromine containing gas, a phosphorus fluoride gas, and an oxygen containing gas, and generate a plasma from the processing gas to etch the silicon film or the silicon-containing conductive film.

In the exemplary embodiments described above, the plasma processing apparatus and the plasma processing method may be modified without departing from the scope and spirit of the present disclosure. For example, some components in an embodiment may be added to another embodiment within the ordinary creative range of a person skilled in the art. Some elements in an embodiment may be replaced with corresponding elements in another embodiment.

1. An etching method comprising:
(a) providing, on a substrate support disposed in a chamber, a substrate that includes:
a silicon film or a silicon-containing conductive film; and
a mask on the silicon film or the silicon-containing conductive film, and
(b) supplying, into the chamber, a processing gas that contains a bromine containing gas, a phosphorus fluoride gas, and an oxygen containing gas, and generating a plasma from the processing gas to etch the silicon film or the silicon-containing conductive film.

2. The etching method according to claim 1, wherein
the silicon-containing conductive film is a film containing silicon and germanium or a metal.

3. The etching method according to claim 1, wherein
the mask includes at least one selected from the group consisting of a silicon-containing insulating film, a metal-containing film, and an organic film.

4. The etching method according to claim 1, wherein
in (b), a ratio of a flow rate of the phosphorus fluoride gas to a flow rate of the processing gas is changed.

5. The etching method according to claim 1, wherein
(b) includes
(b1) etching the silicon film or the silicon-containing conductive film with a first plasma generated from a first processing gas that contains the phosphorus fluoride gas at a first flow ratio, and
(b2) etching the silicon film or the silicon-containing conductive film with a second plasma generated from a second processing gas that does not contain a phosphorus fluoride gas or contains a phosphorus fluoride gas at a second flow ratio smaller than the first flow ratio.

6. The etching method according to claim 5, wherein
(b2) is performed after (b1).

7. The etching method according to claim 5, wherein
(b1) is performed after (b2).

8. The etching method according to claim 5, wherein
(b1) and (b2) are repeated a plurality of times.

9. The etching method according to claim 1, wherein
a flow rate of the bromine containing gas is larger than a flow rate of the phosphorus fluoride gas.

10. The etching method according to claim 1, wherein
a flow rate of the bromine containing gas is 10 vol % or more and 99 vol % or less of a flow rate of the processing gas.

11. The etching method according to claim 1, wherein
a flow rate of the phosphorus fluoride gas is 0.1 vol % or more and 50 vol % or less of a flow rate of the processing gas.

12. The etching method according to claim 1, wherein
a ratio of a flow rate of the bromine containing gas to a flow rate of the phosphorus fluoride gas is in a range of 1 to 999.

13. The etching method according to claim 1, wherein
the bromine containing gas is at least one of an HBr gas and a Br₂ gas.

14. The etching method according to claim 1, wherein
the phosphorus fluoride gas is at least one of a PF₃ gas and a PF₅ gas.

15. The etching method according to claim 1, wherein
the oxygen containing gas is at least one selected from the group consisting of an O₂ gas, a CO gas, and a CO₂ gas.

16. An etching method comprising:
(a) providing, on a substrate support disposed in a chamber, a substrate that includes:
a silicon film or a silicon-containing conductive film; and
a mask on the silicon film or the silicon-containing conductive film, and
(b) supplying, into the chamber, a processing gas containing a first gas that contains a first halogen, a second gas that contains a second halogen and phosphorus, and an oxygen containing gas, and generating a plasma from the processing gas to etch the silicon film or the silicon-containing conductive film.

17. The etching method according to claim 16, wherein
the silicon-containing conductive film is a film containing silicon and germanium or a metal.

18. The etching method according to claim 16, wherein
in (b), a ratio of a flow rate of the second gas to a flow rate of the processing gas is changed.

19. The etching method according to claim 16, wherein
the mask includes at least one selected from the group consisting of a silicon-containing insulating film, a metal-containing film, and an organic film.

20. The etching method according to claim 16, wherein
the mask contains at least one selected from the group consisting of silicon oxide, SiON, W, WSi, WSIN, WC, TiN, and TiO.

21. The etching method according to claim 16, wherein
the first gas is at least one selected from the group consisting of an HBr gas, a Br₂ gas, and a Cl₂ gas.

22. The etching method according to claim 16, wherein
the second gas is at least one selected from the group consisting of a PF₃ gas, a PF₅ gas, and a PCl₃ gas.

23. A plasma processing apparatus comprising:
a chamber,
a substrate support disposed in the chamber,
a plasma generator, and
a controller having a processor and a memory with a computer readable program stored therein that upon execution of the computer readable program by the processor configures the controller to execute:
(a) control to provide, on the substrate support, a substrate that includes:
a silicon film or a silicon-containing conductive film; and
a mask on the silicon film or the silicon-containing conductive film, and
(b) control to supply, into the chamber, a processing gas that contains a bromine containing gas, a phosphorus fluoride gas, and an oxygen containing gas, and generate a plasma from the processing gas to etch the silicon film or the silicon-containing conductive film.
